(19) United States
(12) Patent Application Publication
(10) Pub. No.: US 2006/0166457 A1
(43) Pub. Date: Jul. 27, 2006

(54) Method of making transistors and non-silicided polysilicon resistors for mixed signal circuits

(76) Inventors: Sarah X. Liu, Plano, TX (US); Greg C. Baldwin, Plano, TX (US); Haowen Bu, Plano, TX (US); Shashank S. Ekbote, Allen, TX (US)

Correspondence Address: TEXAS INSTRUMENTS INCORPORATED, P O BOX 655474, M/S 3999, DALLAS, TX, 75265, US

(21) Appl. No.: 11/040,749

(22) Filed: Jan. 21, 2005

(51) Int. Cl. H01L 21/336

(52) U.S. Cl. 438/400

(57) ABSTRACT

A method for manufacturing a semiconductor wafer 10 that includes implanting source/drain regions 75 within a top surface of the semiconductor substrate 20, forming a dielectric capping layer 170 over the semiconductor wafer 20, and annealing the semiconductor wafer 10 to activate sources/drains 70. The method further includes forming a layer of photoresist 180 and then patterning the layer of photoresist 180 to protect a middle portion of the polysilicon layer 100 of the non-silicided poly resistor stacks 30, etching the exposed portions of the dielectric capping layer 170, and removing the patterned photoresist 180. A layer of silicidation metal 190 is formed over the semiconductor wafer 10, and a silicide anneal is performed to create a silicide 160 within a top surface of said sources/drains 70 and also within unprotected top portions of the polysilicon layer 100 of the non-silicided poly resistors 30. Then the remaining portions of the dielectric capping layer 170 are etched.

### BACKGROUND OF THE INVENTION

This invention relates to the fabrication of transistors and non-silicided polysilicon resistors on semiconductor wafers.

### BRIEF DESCRIPTION OF THE DRAWINGS

FIG. 1 is a cross-sectional view of a semiconductor wafer in accordance with the present invention.

FIGS. 2A-2M are cross-sectional diagrams of a process for forming a portion of a mixed signal integrated circuit in accordance with the present invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Referring to the drawings, FIG. 1 is a cross-sectional view of a semiconductor wafer 10 in accordance with the present invention. In the example mixed signal (i.e. analog and digital) integrated circuit application, non-silicided poly block resistors 30 and CMOS transistors 40 are formed within a semiconductor substrate 20 having an NMOS or PMOS region 50. In this example application, the CMOS transistor 40 is a NMOS transistor that is formed within a p-well region 50 of the semiconductor substrate 20.

The CMOS transistors 40 of the mixed signal circuit are electrically insulated from other active devices (not shown) by field oxide regions (also known as Shallow Trench Isolation or “STI” regions) 60 formed within the semiconductor substrate 20; however, any conventional isolation structure may be used such as LOCOS structures or implanted isolation regions. The semiconductor substrate 20 is a single-crystalline substrate that is doped to be n-type and p-type; however, it may also be formed by fabricating an epitaxial silicon layer on a single-crystal substrate.

In general, transistors are comprised of a gate, source, and drain. More specifically, as shown in FIG. 1, the active portion of the transistors are comprised of sources/drains 70, source/drain extensions 80, and a gate stack that is comprised of a layer of gate oxide 90 and a layer of gate polysilicon 100.

The example NMOS transistor 40 is an n-channel MOS transistor. Therefore it is formed within a p-well region 50 of the semiconductor substrate 20. In addition, the heavily doped sources and drains 70 (as well as the medium doped source and drain extensions 80) have n-type dopants. The NMOS gate would be created from a n-type doped gate polysilicon electrode 100 and a gate oxide dielectric 90.

A sidewall structure comprising offset layers 110, 120 are used during fabrication to enable the proper placement of the sources/drains 70 and the source/drain extensions 80 respectively. Usually the source/drain extensions 80 are formed using the gate stack 90, 100 and the extension sidewalls 110 as a mask. Similarly, the sources/drains 70 are usually formed with the gate stack 90, 100 and the spacer sidewalls 120 as a mask.

In the example mixed signal application, non-silicided poly resistors 30 are formed over selected field oxide regions 60. The non-silicided poly resistors include extension sidewalls 110, spacer sidewalls 120, and a resistor stack that includes an oxide layer 90 and a polysilicon layer 100. The non-silicided polysilicon resistors generally have a higher resistance than other polysilicon resistors because the sidewalls 110, 120 and a dielectric capping layer (described below) protect the bulk (i.e. the main body) of the polysilicon from silicidation with metals such as cobalt and nickel. It is to be noted that a relatively thin suicide film is formed on the outside portions of the polysilicon surface (i.e. the head of the resistor) during fabrication in order to facilitate electrical connections between the non-silicided poly resistor 30 and other active devices within the mixed signal circuit. In general, non-silicided poly resistors possess better temperature coefficient characteristics for mixed signal applications.

Immediately above and surrounding the resistors 30 and transistors 40 is a layer of dielectric insulation 130. The composition of dielectric insulation 130 may be any suitable material such as SiO₂ or organosilicate glass (“OSG”). The dielectric material 130 electrically insulates the metal contacts 140 that electrically connect the non-silicided poly resistors and CMOS transistors (shown in FIG. 1) to other active or passive devices (not shown) that are located throughout the semiconductor substrate 20. An optional dielectric liner (not shown) may be formed before the placement of the dielectric insulation layer 130. If used, the dielectric liner may be any suitable material such as silicon nitride.

In the example application, the metal contacts 140 are comprised of W; however, any suitable material (such as Cu, Ti, or Al) may be used. In addition, an optional contact liner 150 containing conductive material such as Ti, TiN, or Ta (or any combination or layer stack thereof) may be used to reduce the resistance at the interface between the liner 150 and the silicided regions 160 of the gate polysilicon 100, the sources/drains 70, and the resistor polysilicon layer 100. In accordance with the invention, the silicide 160 is CoSi₂. However, it is within the scope of the invention to use a different silicide, such as NiSi.

Subsequent fabrication will create the “back-end” portion of the integrated circuit (not shown). The back-end generally contains one or more interconnect layers (and possibly via layers) that properly route electrical signals and power though out the completed integrated circuit.

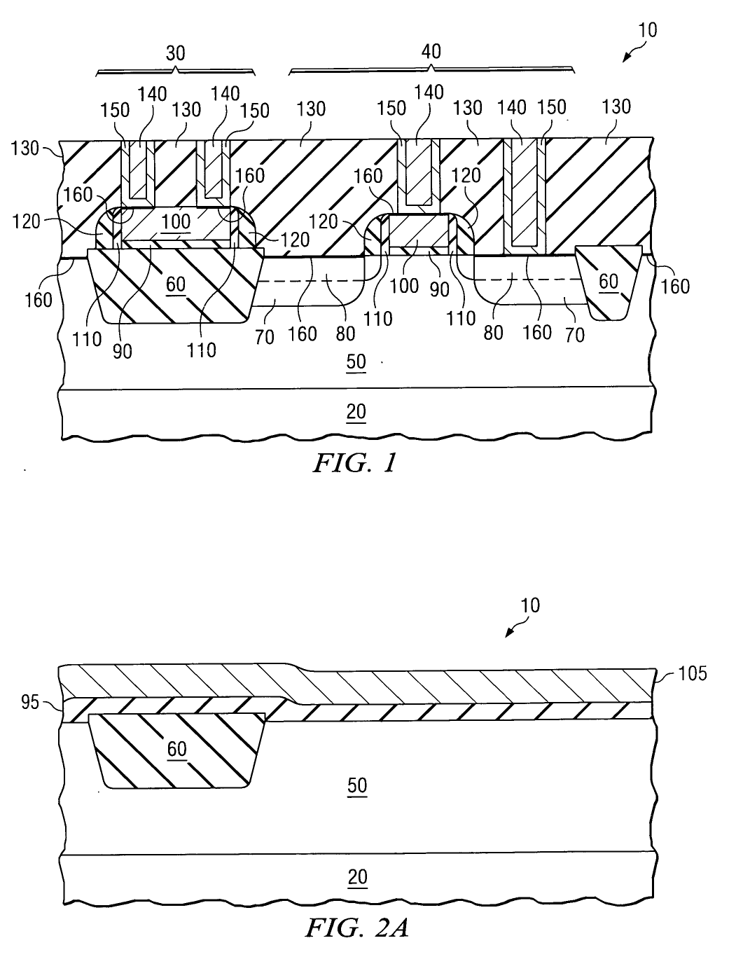

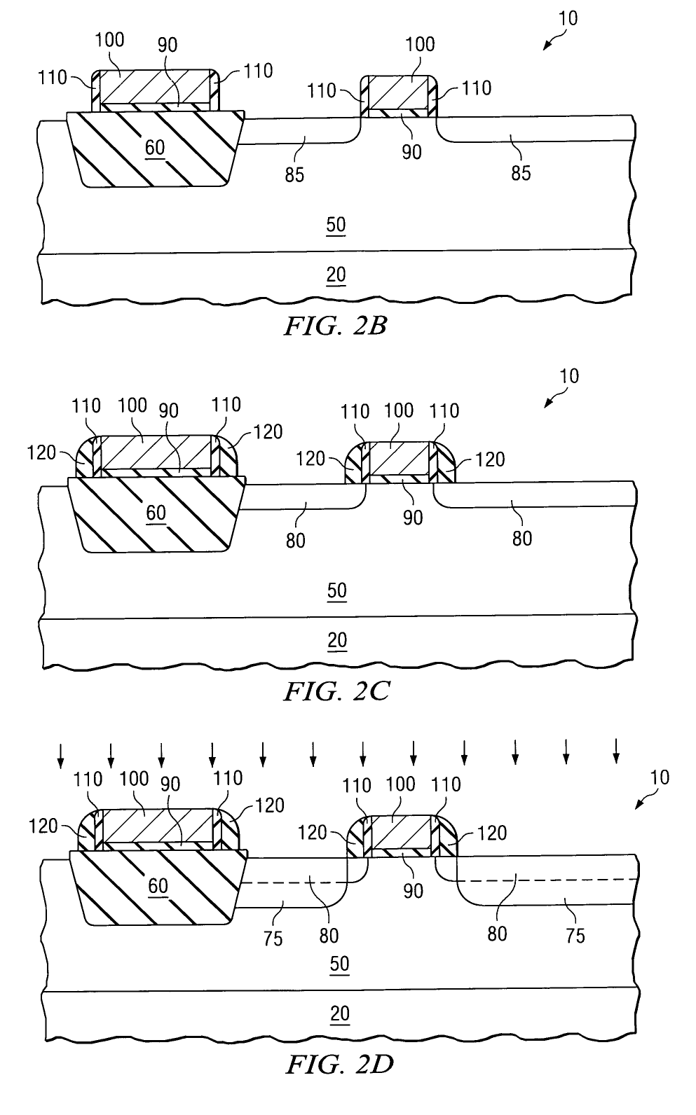

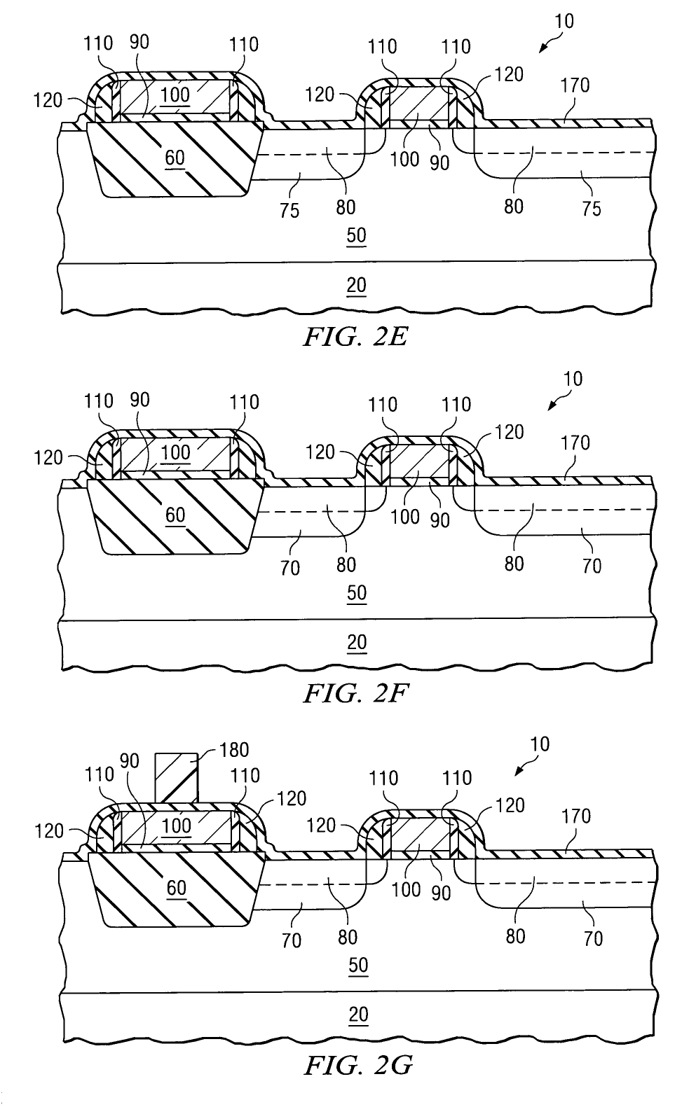

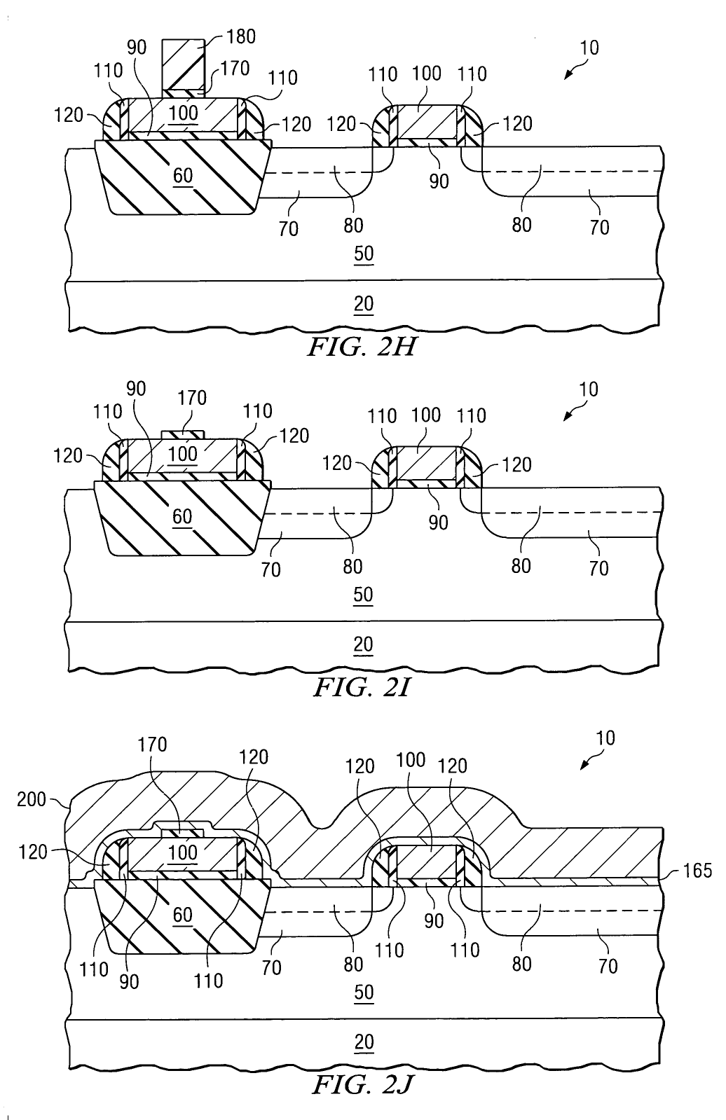

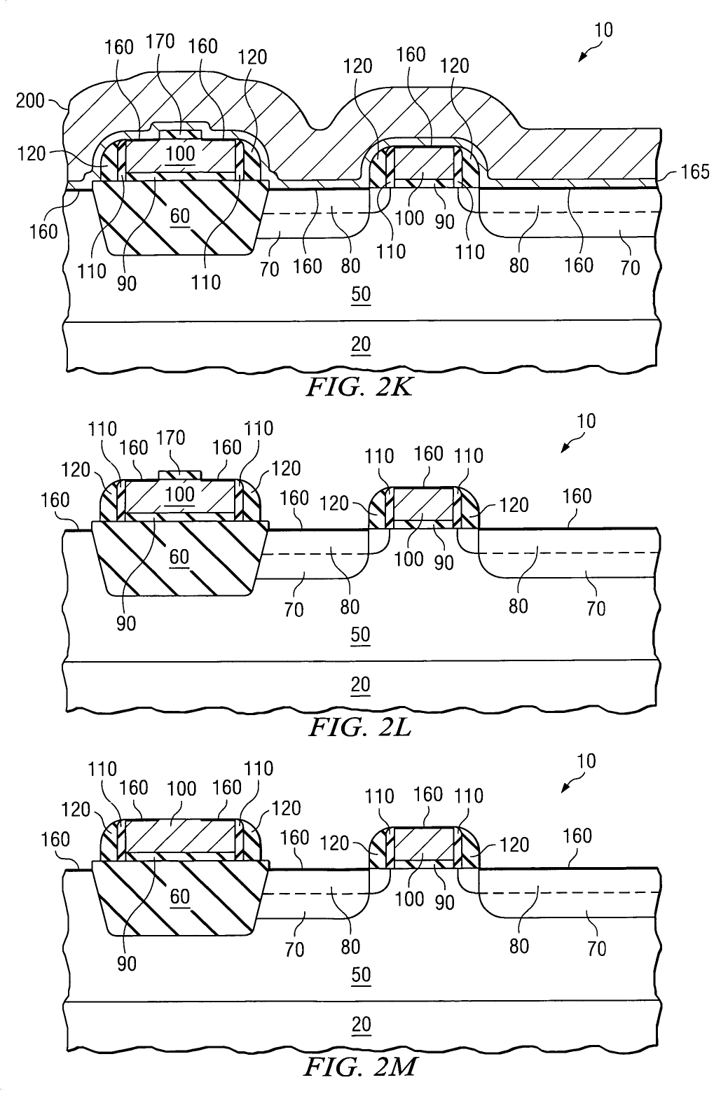

Referring again to the drawings, FIGS. 2A-2M are cross-sectional views of a partially fabricated semiconductor wafer that illustrate a process for forming an example non-silicided poly resistor 30 and NMOS transistor 40 of a mixed signal integrated circuit in accordance with one embodiment of the present invention. Those skilled in the art of semiconductor fabrication will easily understand how to modify this process to manufacture other types of transistors in accordance with this invention.

FIG. 2A is a cross-sectional view of a semiconductor wafer 10 after the formation of the STI structure 60 within the semiconductor substrate 20, the oxide layer 95, and the polysilicon layer 105 on the top surface the semiconductor substrate 20. These elements are formed using processes and materials that are standard in the industry, as outlined below.

In the example application, the semiconductor substrate 20 is silicon; however any suitable material such as germanium or gallium arsenide may be used. As shown in FIG. 2A, the example non-silicided polysilicon resistor 30 and NMOS transistor 40 are formed within a p-well region 50 of the semiconductor substrate 20. The field oxide regions 60 are formed within the top surface of the semiconductor substrate 20 by forming a layer of photoresist over the semiconductor substrate, patterning the photoresist to expose the locations for the field oxide regions 60, and then performing an oxidation process to grow the field oxide regions 60 within the top surface of the semiconductor substrate 20 (and thereafter removing the photoresist).

The first layer that is formed over the surface of the semiconductor substrate 20 is an oxide layer 95. Preferably, the oxide layer 95 is comprised of silicon dioxide formed during a thermal oxidation process. However, the oxide layer 95 may be comprised of any suitable material, such as nitrided silicon oxide, silicon nitride, or a high-k gate dielectric material. In addition, it may be formed using any one of a variety of processes such as an oxidation process or a thermal nitridation process. It is to be noted that in situations where a thermal oxide is used as the gate oxide 95, the thickness of the thermal oxide layer is negligible over the field oxide regions 60.

A polysilicon layer 105 is then formed on the surface of the oxide layer 95. The polysilicon layer 105 is comprised of polycrystalline silicon in the example application. However, it is within the scope of the invention to use other materials such as an amorphous silicon, a silicon germanium alloy, a bi-layer of amorphous silicon and polysilicon, or other suitable materials. The polysilicon layer 105 may be formed using any process technique such as chemical vapor deposition (“CVD”) or physical vapor deposition (“PVD”).

After a standard pattern and etch process, a gate stack and a resistor stack having oxide portions 90 and 100, respectively, will be formed from the oxide layer 95 and the polysilicon layer 105. The resistor stack will be formed above the field oxide region 60 in order to electrically isolate the non-silicided poly resistor from the other active and passive elements formed within the semiconductor substrate 20. Conversely, the gate stack will be formed between field oxide regions 60 in order to facilitate the implantation of the sources/drains 70 within the surface of the semiconductor substrate 20 on either side of the gate stack. These gate and resistor stacks, shown in FIG. 2B, may be created through a variety of processes. For example, the stacks may be created by forming a layer of photoresist over the semiconductor wafer, patterning the photoresist, and then using the photoresist pattern to etch both the oxide layer 95 and the polysilicon layer 105. The stacks may be etched using an suitable etch process, such as a wet or dry etch.

The fabrication of the non-silicided polysilicon resistor 30 and the NMOS transistor 40 now continues with standard process steps. Generally, the next step in the semiconductor wafer manufacturing process is the formation of the source/drain extensions 80. As shown in FIG. 2B, extension sidewalls 110 are now formed on the outer surfaces of the resistor stack and the gate stack. The extension sidewalls 110 may be comprised of an oxide, oxi-nitride, silicon dioxide, nitride, or any other dielectric material or layers of dielectric materials. Furthermore, the extension sidewalls 110 may be formed with any suitable process, such as thermal oxidation, deposited oxide, CVD, or PVD.

These extension sidewalls 110 are now used as a template to facilitate the proper placement of the extension regions 85, as shown in FIG. 2B. However, it is within the scope of the invention to form the extension regions 85 at any point in the manufacturing process. The extension regions 85 are formed near the top surface of the doped semiconductor substrate 50 using any standard process. For example, the extension regions 85 may be formed by low-energy ion implantation, a gas phase diffusion, or a solid phase diffusion. The dopants used to create the extension regions 85 for a NMOS transistor 40 are n-type (i.e. As or P). However, other dopants or combinations of dopants may be used.

The extension sidewalls 110 are used to direct the dopant implantation to the proper location 85 within the semiconductor substrate 20. Thus, the source and drain extension regions 85 initiate from points in the semiconductor substrate 20 that are approximately at the outer corner of the extension sidewalls 110. At some point after the implantation of the extension regions 85, the extension regions 85 are activated by an anneal process (performed now or later). This anneal step may be performed with any suitable process such as rapid thermal anneal (“RTA”). The annealing process will likely cause a lateral migration of each source/drain extension toward the opposing extension region 85 (as shown in FIG. 2C) and form the source/drain extensions 80.

Referring to FIG. 2C, spacer sidewalls 120 are now formed proximate to the extension sidewalls 110 of the gate stack and the resistor stack. The spacer sidewalls 120 may be formed using any standard process. For example, the spacer sidewalls 120 may be comprised of an oxide, nitride, or any other dielectric material or layers of materials that are formed with a CVD process and subsequently anisotropically etched. Now the spacer sidewalls 120 (and the gate polysilicon 100) are used as a template for the transistor source/drain implantation step.

The next step in the fabrication of the semiconductor wafer 10 is the implantation of dopants into the source and drain regions 75 within the top surface of the semiconductor substrate 20, as shown in FIG. 2D. The source/drain regions 75 may be formed through any one of a variety of processes, such as deep ion implantation or deep diffusion. The dopants used to create the source/drain regions 75 for a NMOS transistor are typically P or As; however, other dopants or combinations for dopants may be used. The implantation of the dopants is self-aligned with respect to the outer edges of the spacer sidewalls 120. It is to be noted that during the implantation of the source/drain regions, exposed silicon—such as the gate polysilicon 100 and resistor polysilicon 100—will also receive implanted dopants. Thus, the conductivity of the NMOS transistor gate and the resistor will be changed by this implantation step. The amount of change will depend on the dose and energy of the implanted species.

In accordance with the invention, the next step is the formation of a dielectric capping layer 170 over the semiconductor wafer 10, as shown in FIG. 2E. The thickness of the dielectric capping layer may range from 7 nm to 120 nm. Preferably, the dielectric capping layer is comprised of a layer of thin oxide (i.e. silicon oxide) that is subsequently covered by a layer of nitride (i.e. silicon nitride). Moreover, the layer of oxide is approximately 5 nm thick, but may have any thickness between 2 and 20 nm. The layer of nitride is approximately 30 nm thick, but may have any thickness between 5 and 100 nm. However, it is within the scope of the invention to use other materials and one or more layers as the dielectric capping layer 170. For example, the dielectric capping layer 170 may comprise a single layer of oxide.

In the example application, the oxide layer is formed over the entire surface of the semiconductor wafer 10 with a plasma-enhanced chemical vapor deposition (“PECVD”) process (using any suitable machine, such as the Centura manufactured by Applied Materials (“AMAT”)); however, any other suitable process may be used. In the best mode application, the deposition is performed at a temperature between 300-500° C., and preferably at around 350° C. In addition, the deposition is performed at a RF power between 100-150 watts and a pressure between 5-10 torr. Furthermore, the deposition is performed with a silane flow (i.e. SiH₄) between 10-30 standard cubic centimeters per minute (“sccm”) and a nitrous oxide flow (i.e. N₂O) between 300-600 sccm.

Next, the nitride layer is formed over the oxide layer using the same process and machine in-situ. In the best mode application, the deposition is performed at a temperature between 300-500° C., and preferably at around 350° C. In addition, the deposition is performed at a RF power between 100-150 watts and a pressure between 5-10 torr. Furthermore, the deposition is performed with a silane flow (i.e. SiH₄) between 60-100 standard cubic centimeters per minute (“sccm”) and an ammonia flow (i.e. NH₃) between 150-300 sccm. This combination oxide/nitride dielectric capping layer 170 will cover the semiconductor wafer 10 during the upcoming source/drain annealing process. Using this best mode application, the nitride film is expected to impart a stress of 100-300 MPa to the underlying devices.

In the example application, the sources/drains 70 are activated by an anneal process. This anneal step acts to repair the damage to the semiconductor wafer and to activate the dopants. The activation anneal is preferably performed by a rapid thermal anneal (“RTA”, sometimes called “spike anneal”) process; however, any technique may be used, such as flash lamp annealing (“FLA”), or laser annealing. This anneal step often causes both lateral and vertical migration of dopants and forms the sources/drains 70, as shown in FIG. 2F.

This anneal step causes the intrinsic stress to increase. Thus, the dielectric cap layer now imparts a higher tensile stress to the underlying devices. Furthermore, the hydrogen atoms that were released from the dissociation of the Si—H and N—H bonds in the film now modify the dopant redistribution; thereby creating a retrograde dopant profile in the NMOS channel region. This combination of the stress effect and the modification of the dopant redistribution cause an enhancement of the electron mobility within the channel region. As a result, the transistor drive current is improved.

In accordance with the invention, the dielectric capping layer 170 is selectively removed from all areas except the middle portion of the polysilicon surface 100 of the resistor stack 30. In the example application, a standard photoresist process is used to pattern the dielectric capping layer 170 for the selective removal of the dielectric capping layer. Specifically, a layer of any suitable photoresist material is formed over the semiconductor wafer 10 and subsequently patterned with standard lithography and ashing processes to create a patterned photoresist 180 overlying the non-silicided poly resistor 30, as shown in FIG. 2G.

The patterned photoresist 180 is used as a template to etch the exposed dielectric capping layer 170 while simultaneously protecting the middle portion of the polysilicon layer 100 of the non-silicided polysilicon resistor 30, as shown in FIG. 2H. Preferably, a dry etch process with a fluorine-based chemistry is used to etch the dielectric capping layer 170; however any suitable process may be utilized, such as a wet etch process using phosphoric acid or diluted hydrofluoric acid. The remaining photoresist 180 is now removed with a standard ashing process—leaving a portion of the original dielectric capping layer 170 over the non-silicided polysilicon resistor 30, as shown in FIG. 21.

In the example application, a standard silicidation process is now used to create silicides 160. As shown in FIG. 2J, a layer of silicidation metal 165 is formed over the top surface of the semiconductorwafer 10. The silicidation metal layer 165 is preferably comprised of Co; however, other suitable materials such as Ni, Ta, Ti, W, Mo, or Pt may be used. An optional silicidation capping layer 200 may also be formed over the silicidation metal layer 165. If used, the silicidation capping layer 200 acts as a passivation layer that prevents the diffusion of oxygen from ambient into the silicidation metal layer 165. The silicidation capping layer 200 may be any suitable material, such as TiN.

In accordance with the invention, the semiconductor wafer 10 is now annealed with any suitable process, such as RTA. This silicide anneal process will cause a silicide 160 (i.e. a Co-rich silicide or Co mono-silicide) to form at the exposed surface of the sources/drains 70, at the surface of the gate polysilicon 100, and the exposed surface of the non-silicided poly resistor polysilicon 100. These silicide regions 160 are shown in FIG. 2K. It is to be noted that the silicidation metal layer 165 will only react with the active substrate (i.e. exposed Si); namely, the gate polysilicon 100, the resistor polysilicon 100, and the sources/drains 70. Therefore, the silicide 160 formed by the annealing process is considered a self-aligned silicide (“salicide”). It is to be noted that any exposed semiconductor substrate 20 active area not associated with any active device will also form a silicide 160, as shown in FIG. 2K.

As shown in FIG. 2L, the next step is the removal of the unreacted portions of the silicidation metal layer 165 (and the silicidation capping layer 200, if used) through a wet etch process (i.e. using a mixture of sulfuric acid, hydrogen peroxide, and water). It is within the scope of the invention to perform a second anneal (such as a RTA) at this point in the manufacturing process in order to further react the silicide 160 with the sources/drains 70, the gate polysilicon 100, and the non-silicided resistor polysilicon 100. If the initial silicide anneal process did not complete the silicidation process, this second anneal will ensure the formation of a mono-silicide CoSi₂ which lowers the sheet resistance of the silicide 160.

In accordance with the invention, the remaining dielectric capping layer 170 is now removed with the same process used above (i.e. dry etch with fluorine-based chemistries). The semiconductor wafer 10 at this stage of the fabrication process is shown in FIG. 2M.

It is to be noted that in the best mode application of the invention the dielectric capping layer 170 served a dual purpose. First, it was the hardmask layer used to form non-silicided poly resistors 30 within a mixed signal integrated circuit. Second, it improved the NMOS drive current through its stress effect and dopant modification/red istribution.

The fabrication of the semiconductor wafer now continues, using standard process steps (see FIG. 1). Generally, the next step is the formation of the dielectric insulator layer 130. The dielectric insulator layer 130 may be formed using a PECVD or another suitable process. The dielectric insulator 130 may be comprised of any suitable material such as SiO₂ or OSG.

The contacts 140 are formed by etching the dielectric insulator layer 130 to expose the desired resistor contacts, gate, source and/or drain. An example etch process is anisotropic etch. The etched spaces are usually filled with a liner 150 to improve the electrical interface between the silicides 160 and the contacts 140. Then contacts 140 are formed within the liners 150; thereby forming the electrical interconnections between various semiconductor components located within the semiconductor substrate 20.

The fabrication of the final integrated circuit continues with the fabrication of the back-end structure discussed above. Once the fabrication process is complete, the integrated circuit will be tested and then packaged.

Various additional modifications to the invention as described above are within the scope of the claimed invention. As an example, the extension region anneal and the source/drain region anneal may be combined and performed after the formation of the dielectric capping layer 170. In addition, a cleaning process may be performed after any step in the fabrication process. For example, it is usually advantageous to clean the semiconductor wafer 10 after every photoresist ashing process. Similarly, an anneal process may be performed after any step in the fabrication process. When used, the anneal process can improve the microstructure of the materials and thereby improve the quality of the semiconductor structure.

Depending on the application, it may be possible to optimize the etch selectivity and/or enhance the stress effect by using other materials such as silicon carbide (SiC) or nitrided silicon carbide (SiCN) for the dielectric capping layer 170. Instead of using As or P for the n-type dopant, other suitable dopants such as Sb may be used. Furthermore, interfacial layers may be formed between any of the layers described. Moreover, this invention may be implemented in other semiconductor structures such as biCMOS and bipolar transistors.

While various embodiments of the present invention have been described above, it should be understood that they have been presented byway of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for manufacturing a semiconductor wafer, comprising:
providing a semiconductor substrate;
forming field oxide regions within a top surface of said semiconductor substrate;
forming resistor stacks above selected said field oxide regions and forming gate stacks between selected said field oxide regions, said resistor stacks and said gate stacks having an oxide layer and a polysilicon layer;
forming extension sidewalls coupled to said gate stacks and said resistor stacks;
implanting extension regions within a top surface of said semiconductor substrate;
forming spacer sidewalls coupled to said extension sidewalls;
implanting source/drain regions within a top surface of said semiconductor substrate;
forming a dielectric capping layer over said semiconductor wafer;
annealing said semiconductor wafer to activate sources/drains;
forming a layer of photoresist and then patterning said layer of photoresist to protect a middle portion of said polysilicon layer of said resistor stacks;
etching exposed portions of said dielectric capping layer;
removing said patterned photoresist;
forming a layer of silicidation metal over said semiconductor wafer;
performing a silicide anneal to create a silicide within a top surface of said sources/drains and also within unprotected top portions of said polysilicon layer of said resistor stacks; and
etching remaining portions of said dielectric capping layer.

2. The method of claim 1 wherein said dielectric capping layer comprises a layer of silicon oxide below a layer of silicon nitride.

3. The method of claim 2 wherein said dielectric capping layer has a thickness between 7-120 nm.

4. The method of claim 1 wherein said steps of etching exposed portions of said dielectric capping layer and etching remaining portions of said dielectric capping layer comprises a dry etch.

5. The method of claim 1 wherein said layer of silicidation metal comprises Co.

6. The method of claim 1 wherein said silicide is a self-aligned silicide.
